(19) United States
(12) Patent Application Publication
(10) Pub. No.: US 2003/0190773 A1
(43) Pub. Date: Oct. 9, 2003

(54) Method for manufacturing semiconductor device using shallow trench isolation process

(75) Inventor: Yuichi Takada, Kanagawa (JP)

Correspondence Address: SUGHRUE, MION, ZINN, MACPEAK & SEAS, 2100 Pennsylvania Avenue, N.W., Washington, DC, 20037, US

(73) Assignee: NEC ELECTRONICS CORPORATION

(21) Appl. No.: 10/401,969

(22) Filed: Mar. 31, 2003

(30) Foreign Application Priority Data
Apr. 5, 2002 (JP) 2002-103813

(51) Int. Cl. H01L 21/8238

(52) U.S. Cl. 438/200

(57) ABSTRACT

In a method for manufacturing a semiconductor device using a shallow trench isolation process, a silicon substrate is etched using a patterned silicon nitride layer as a mask to form a trench in the silicon substrate. Then, an insulating layer is formed in the trench and on the patterned silicon nitride layer. Then, a chemical mechanical polishing operation is performed upon the insulating layer to expose the patterned silicon nitride layer. Then, after the patterned silicon nitride layer is removed to expose the silicon is substrate, an annealing and oxidizing operation is performed upon the silicon substrate in an oxygen atmosphere or a water steam atmosphere diluted by rare gas, to grow a sacrifice silicon oxide layer on the silicon substrate.

### BACKGROUND OF THE INVENTION

1. Field of the Invention

The present invention relates to a method for manufacturing a semiconductor device, and more particularly, to a method for manufacturing a semiconductor device having a groove-type isolation layer using a shallow trench isolation (STI) process.

2. Description of the Related Art

Recently, metal oxide semiconductor (MOS) devices have been more fine-structured. On the other hand, in order to increase the integration, as technology for forming a field insulating layer, an STI process has been adopted instead of a local oxidation of silicon (LOCOS) process.

In a prior art method for manufacturing a semiconductor device using an STI process, a silicon substrate is etched using a patterned silicon nitride layer as a mask to form a trench in the silicon substrate. Then, an insulating layer is formed in the trench and on the pattern silicon nitride layer. Then, a chemical mechanical polishing (CMP) operation is performed upon the insulating layer to expose the patterned silicon nitride layer. Then, after the patterned silicon nitride layer is removed to expose the silicon substrate, an annealing and oxidizing operation is performed upon the silicon substrate in an oxygen atmosphere diluted by nitrogen gas, to grow a sacrifice silicon oxide layer on the silicon substrate. This will be explained later in detail.

In the above-described prior art method, however, since silicon nitride members are formed on the silicon substrate in the annealing and oxidizing operation to make the surface of the silicon substrate uneven, the reliability of the device would deteriorate.

### SUMMARY OF THE INVENTION

It is an object of the present invention to provide a method for manufacturing a semiconductor device using an STI process capable of improving the reliability of the device.

According to the present invention, in a method for manufacturing a semiconductor device using an STI process, a silicon substrate is etched using a patterned silicon nitride layer as a mask to form a trench in the silicon substrate. Then, an insulating layer is formed in the trench and on the pattern silicon nitride layer. Then, a CMP operation is performed upon the insulating layer to expose the patterned silicon nitride layer. Then, after the patterned silicon nitride layer is removed to expose the silicon substrate, an annealing and oxidizing operation is performed upon the silicon substrate in an oxygen atmosphere or a water steam atmosphere diluted by rare gas, to grow a sacrifice silicon oxide layer on the silicon substrate. As a result, the silicon nitride members in the prior art are never formed on the surface of the silicon substrate.

### BRIEF DESCRIPTION OF THE DRAWINGS

The present invention will be more clearly understood from the description as set forth below, as compared with the prior art, with reference to the accompanying drawings, wherein:

FIGS. 1, 2, 3, 4, 5A, 6A, 7A, 8A, 9 and 10 are cross-sectional views for explaining a prior art method for manufacturing a semiconductor device;

FIGS. 5B, 6B, 7B and 8B are cross-sectional views of partial enlargements of FIGS. 5A, 6A, 7A and 8A, respectively;

FIGS. 11, 12, 13, 14, 15A, 16A, 17A, 18A, 19 and 20 are cross-sectional views for explaining an embodiment of the method for manufacturing a semiconductor device according to the present invention; and

FIGS. 15B, 16B, 17B and 18B are cross-sectional views of partial enlargements of FIGS. 15A, 16A, 17A and 18A, respectively.

### DESCRIPTION OF THE PREFERRED EMBODIMENT

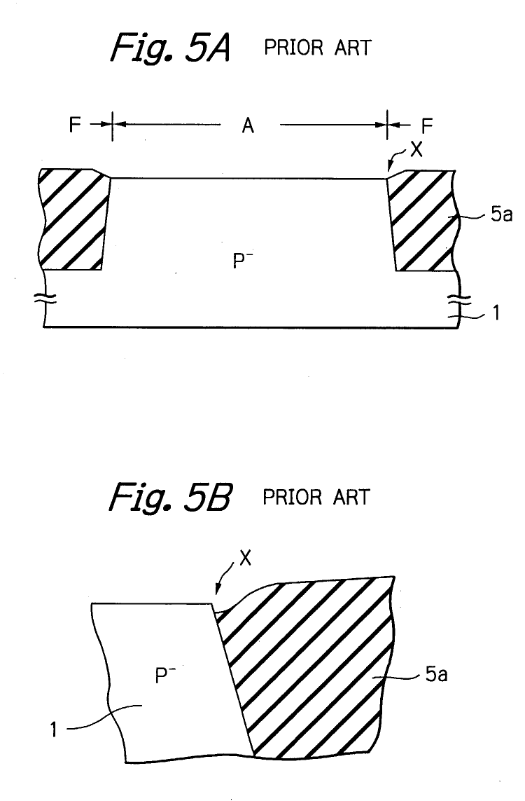

Before the description of the preferred embodiment, a prior art method for manufacturing a semiconductor device such as a MOS transistor will be explained with reference to FIGS. 1, 2, 3, 4, 5A, 5B, 6A, 6B, 7A, 7B, 8A, 8B, 9 and 10. Note that FIGS. 5B, 6B, 7B and 8B are cross-sectional views of partial enlargements of FIGS. 5A, 6A, 7A and 8A, respectively.

First, referring to FIG. 1, an about 5 to 20 nm thick pad silicon oxide layer 2 and an about 100 to 300 nm thick silicon nitride layer 3 are deposited in this sequence on a monocrystalline silicon substrate 1 by a chemical vapor deposition (CVD) process. In this case, the silicon substrate 1 is of a one conductivity type such as a P-type. Then, a photoresist pattern 4 is formed on the silicon nitride layer 3 by a photolithography process to cover an active area A. Note that an area F is called a field area.

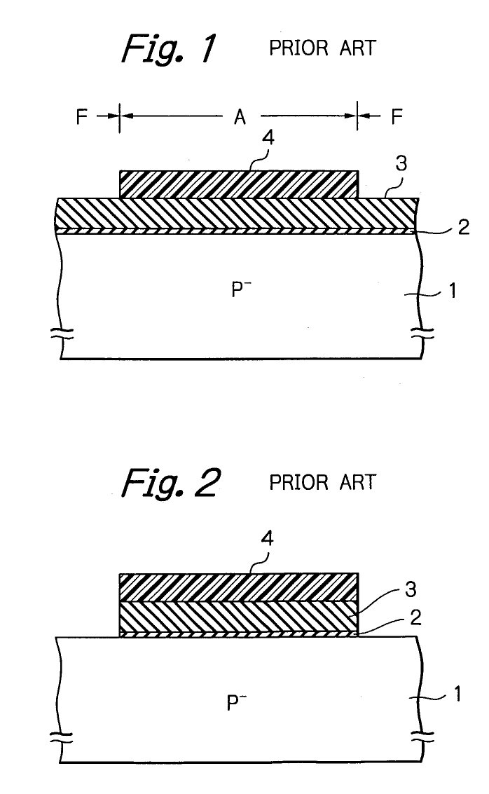

Next, referring to FIG. 2, the silicon nitride layer 3 and the pad silicon oxide layer 2 are etched by a dry etching process using the photoresist pattern 4 as a mask. Then, the photoresist pattern 4 is removed.

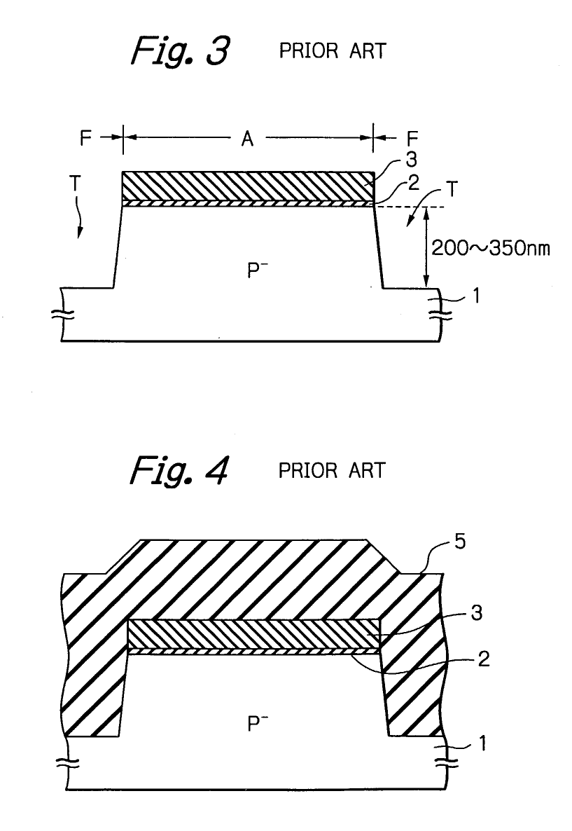

Next, referring to FIG. 3, a part of the silicon substrate 1 whose depth is about 200 to 350 nm is etched by a dry etching process using the silicon nitride layer 3 as a mask. As a result, a trench T is formed in the field area F.

Next, referring to FIG. 4, an about 450 to 650 nm thick insulating layer 5 is deposited on the entire surface, so that the insulating layer 5 is completely buried in the trench T. In this case, the insulating layer 5 is made of undoped silicate glass (USG) by a CVD process or plasma silicon oxide by a high density plasma (HDP) CVD process.

Next, referring to FIG. 5A, a CMP operation is performed upon the insulating layer 5, and then, the silicon nitride layer 3 and the pad silicon oxide layer 2 are removed by a wet etching process. As a result, an STI layer 5a is obtained in the field area F. In this case, as illustrated in FIG. 5B, which is a partial enlargement of the device of FIG. 5A, the edge of the silicon substrate 1 as indicated by X is very sharp, which would create a stress concentration and an electric field concentration therein. Note that such an electric field concentration would increase an off leakage current of MOS transistors.

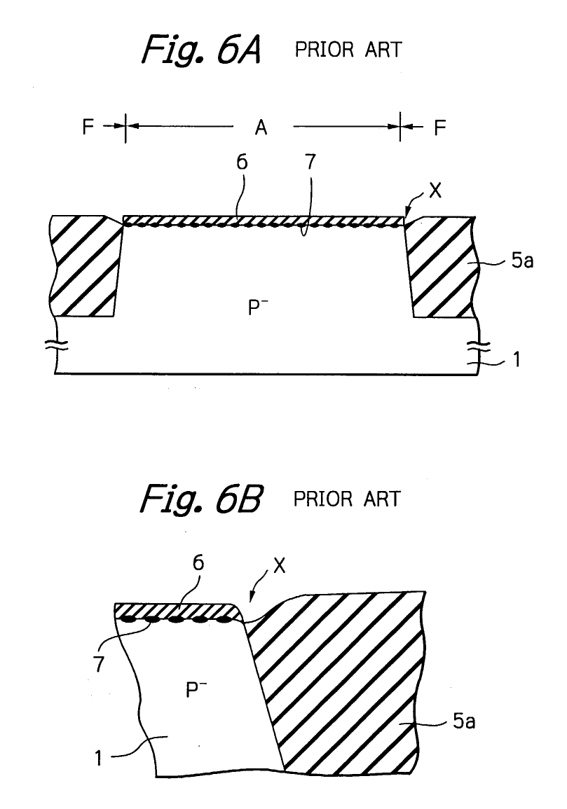

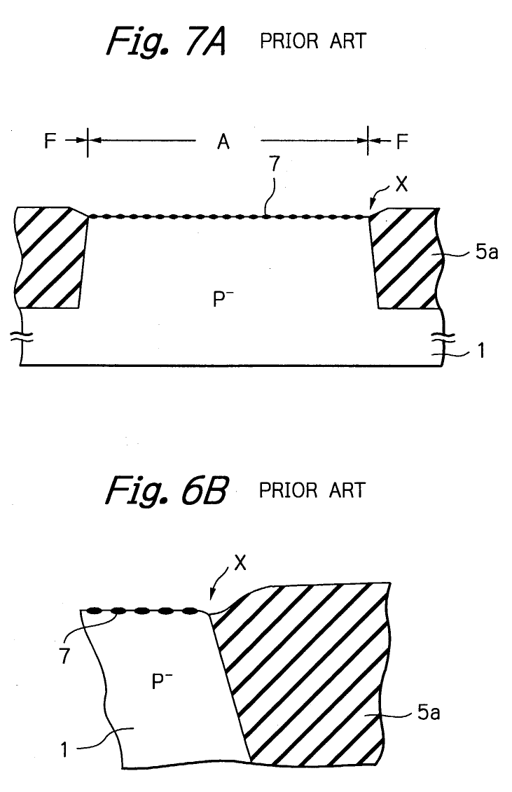

Next, referring to FIG. 6A, an annealing and oxidizing operation is performed upon the silicon substrate 1 in an oxygen atmosphere diluted by nitrogen gas at a temperature of about 1100° C. As a result, the silicon substrate 1 is annealed by nitrogen to relieve the defects and damage on the surface of the silicon substrate 1. Simultaneously, an about 20 to 30 nm thick sacrifice silicon oxide layer 6 is formed on the silicon substrate 1, so that the edge of the silicon substrate 1 is rounded as indicated by X in FIG. 6B which is a partial enlargement of the device of FIG. 6A. As a result, no stress concentration and no electric field concentration would be generated in the edge of the silicon substrate 1.

Also, as illustrated in FIGS. 6A and 6B, since the annealing and oxidizing operation is carried out at a high temperature, parts of the silicon substrate 1 are nitrized, so that silicon nitride members 7 are also generated between the silicon substrate 1 and the sacrifice silicon oxide layer 6.

Thereafter, N-type impurities such as phosphorus ions or arsenic ions are introduced through the sacrifice silicon oxide layer 6 into the silicon substrate 1, thus forming an N-type well (not shown). Also, P-type impurities such as boron ions are introduced through the sacrifice silicon oxide payer 6 into the silicon substrate 1 to adjust a threshold voltage of N-channel MOS transistors, and N-type impurities such as phosphorus ions or arsenic ions are introduced through the sacrifice silicon oxide payer 7 into the N-type well to adjust a threshold voltage of P-channel MOS transistors.

Next, referring to FIGS. 7A and 7B, the sacrifice silicon oxide layer 6 is removed by a wet etching process using diluted fluoric acid. Even in FIGS. 7A and 7B, since the silicon nitride members 7 is not etched by diluted fluoric acid, the silicon nitride members 7 remain.

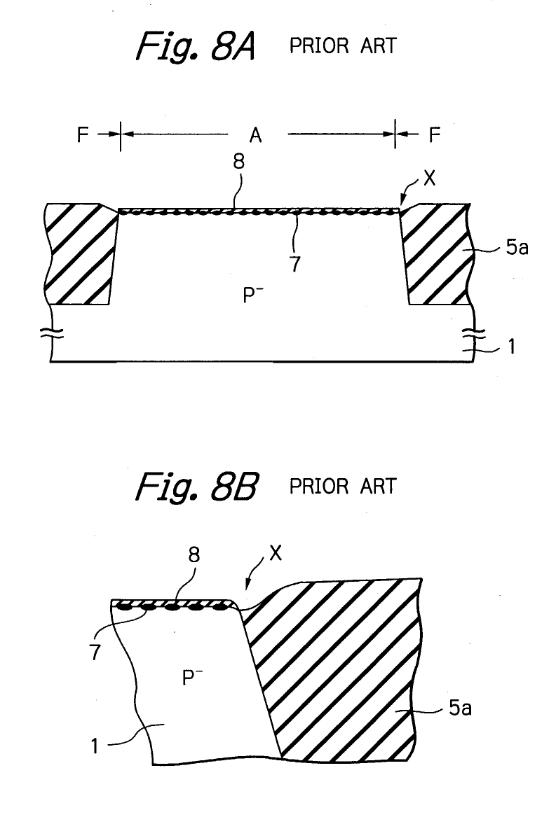

Next, referring to FIGS. 8A and 8B, an about 2 to 10 nm thick gate silicon oxide layer 8 is thermally grown on the silicon substrate 1.

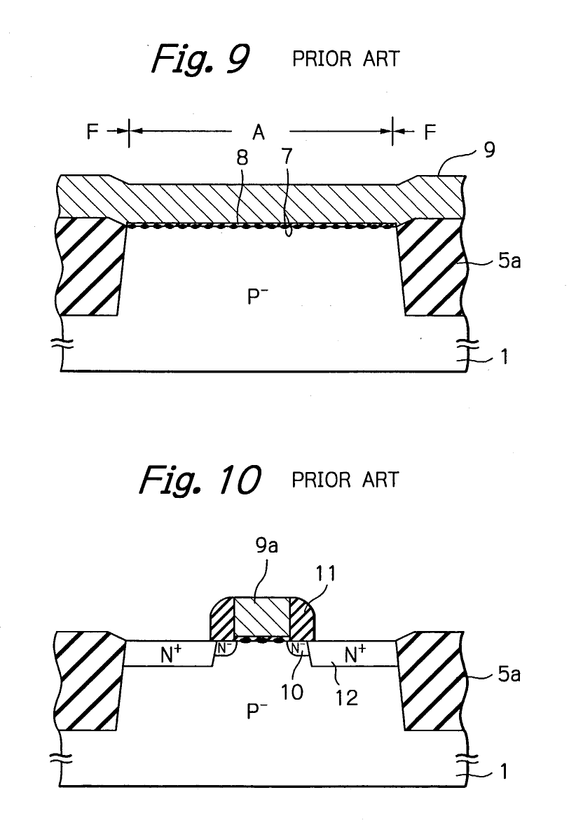

Next, referring to FIG. 9, an about 100 to 200 nm thick polycrystalline silicon layer 9 is deposited on the entire surface by a CVD process.

Finally, referring to FIG. 10, the polycrystalline silicon layer 9 is patterned by a photolithography and etching process, so that a gate electrode 9a is formed. Then, a low concentration impurity diffusion region 10 is formed within the silicon substrate 1 in self-alignment with the gate electrode 9a. Also, a sidewall insulating layer 11 is formed on sidewalls of the gate electrode 9a, and then, a high concentration impurity diffusion region 12 is formed within the silicon substrate 1 in self-alignment with the sidewall insulating layer 11. Thus, a lightly-doped drain (LDD) type MOS device is completed.

In the manufacturing method as illustrated in FIGS. 1, 2, 3, 4, 5A, 5B, 6A, 6B, 7A, 7B, 8A, 8B, 9 and 10, however, since the silicon nitride members 7 are formed on the surface of the silicon substrate 1, the surface of the silicon substrate 1 becomes uneven so that the reliability of the device would deteriorate.

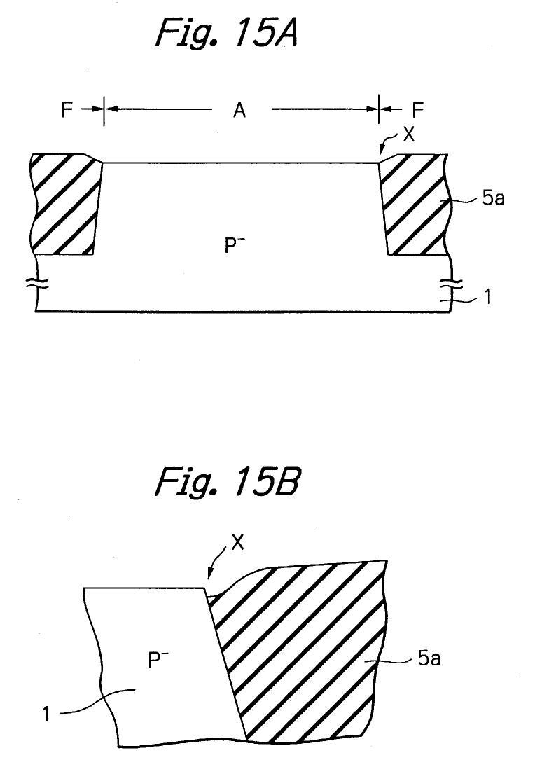

An embodiment of the method for manufacturing a semiconductor device such as a MOS transistor according to the present invention will be explained next with reference to FIGS. 11, 12, 13, 14, 15A, 15B, 16A, 16B, 17A, 17B, 18A, 18B, 19 and 20. Note that FIGS. 15B, 16B, 17B and 18B are cross-sectional views of partial enlargements of FIGS. 15A, 16A, 17A and 18A, respectively.

First, referring to FIG. 11, in the same way as in FIG. 1, an about 5 to 20 nm thick pad silicon oxide layer 2 and an about 100 to 300 nm thick silicon nitride layer 3 are deposited in this sequence on a monocrystalline silicon substrate 1 by a CVD process. In this case, the silicon substrate 1 is of a one conductivity type such as a P-type. Then, a photoresist pattern 4 is formed on the silicon nitride layer 3 by a photolithography process to cover an active area A. Note that an area F is called a field area.

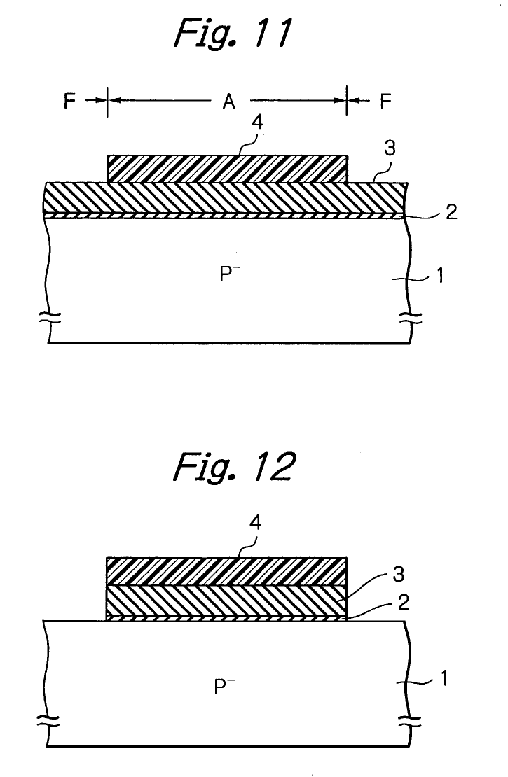

Next, referring to FIG. 12, in the same way as in FIG. 2, the silicon nitride layer 3 and the pad silicon oxide layer 2 are etched by a dry etching process using the photoresist pattern 4 as a mask. Then, the photoresist pattern 4 is removed.

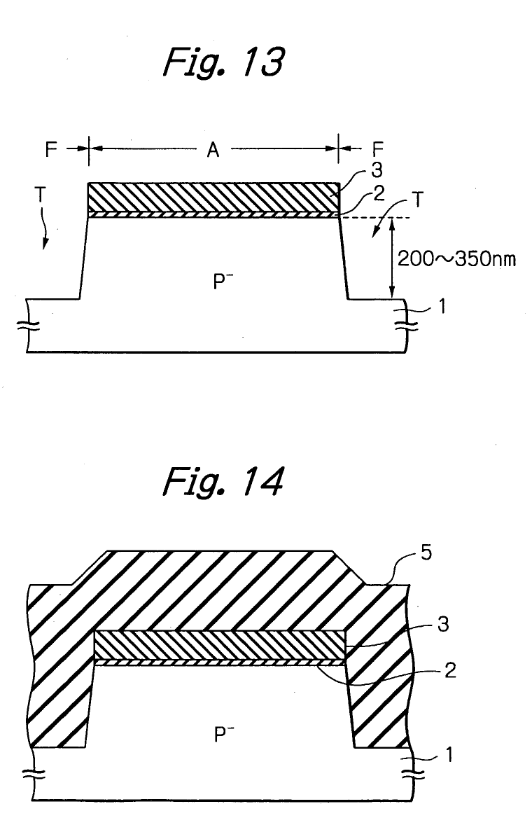

Next, referring to FIG. 13, in the same way as in FIG. 3, a part of the silicon substrate 1 whose depth is about 200 to 350nm is etched by a dry etching process using the silicon nitride layer 3 as a mask. As a result, a trench T is formed in the field area F.

Next, referring to FIG. 14, in the same way as in FIG. 4, an about 450 to 650 nm thick insulating layer 5 is deposited on the entire surface, so that the insulating layer 5 is completely buried in the trench T. In this case, the insulating layer 5 is made of USG by a CVD process or plasma silicon oxide by an HDP CVD process.

Next, referring to FIG. 15A, in the same way as in FIG. 5A, a CMP operation is performed upon the insulating layer 5, and then, the silicon nitride layer 3 and the pad silicon oxide layer 2 are removed by a wet etching process. As a result, an STI layer 5a is obtained in the field area F. In this case, as illustrated in FIG. 15B, which is a partial enlargement of the device of FIG. 15A, the edge of the silicon substrate 1 as indicated by X is very sharp, which would create a stress concentration and an electric field concentration therein. Note that such an electric field concentration would increase an off leakage current of MOS transistors.

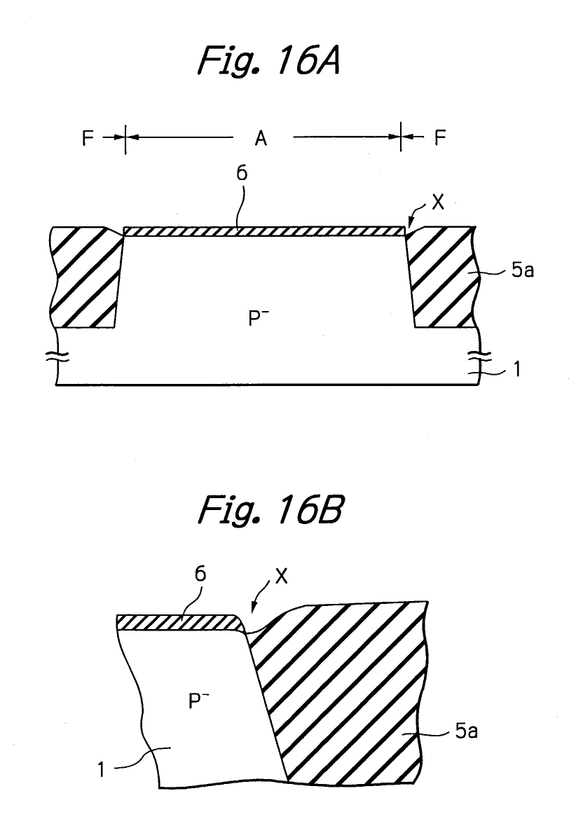

Next, referring to FIG. 16A, an annealing and oxidizing operation is performed upon the silicon substrate 1 in an oxygen atmosphere diluted by rare gas such as He gas, Ne gas, Ar gas, Kr gas, Xe gas or Rn gas at a temperature of about 950° C. to 1200° C., preferably, about 1000 to 1150° C. As a result, the silicon substrate 1 is annealed by the rare gas to relieve the defects and damage on the surface of the silicon substrate 1. Simultaneously, an about 20 to 30 nm thick sacrifice silicon oxide layer 6 is formed on the silicon substrate 1, so that the edge of the silicon substrate 1 is rounded as indicated by X in FIG. 16B which is a partial enlargement of the device of FIG. 16A. As a result, no stress concentration and no electric field concentration would be generated in the edge of the silicon substrate 1.

Also, in this case, as illustrated in FIGS. 16A and 16B, even when the annealing and oxidizing operation is carried out at a high temperature, since nitrogen gas is not used, the silicon substrate 1 is never nitrized, so that the silicon nitride members 7 in the prior art are not generated between the silicon substrate 1 and the sacrifice silicon oxide layer 6.

Thereafter, N-type impurities such as phosphorus ions or arsenic ions are introduced through the sacrifice silicon oxide layer 6 into the silicon substrate 1, thus forming an N-type well (not shown). Also, P-type impurities such as boron ions are introduced through the sacrifice silicon oxide payer 6 into the silicon substrate 1 to adjust a threshold voltage of N-channel MOS transistors, and N-type impurities such as phosphorus ions or arsenic ions are introduced through the sacrifice silicon oxide payer 6 into the N-type well to adjust a threshold voltage of P-channel MOS transistors.

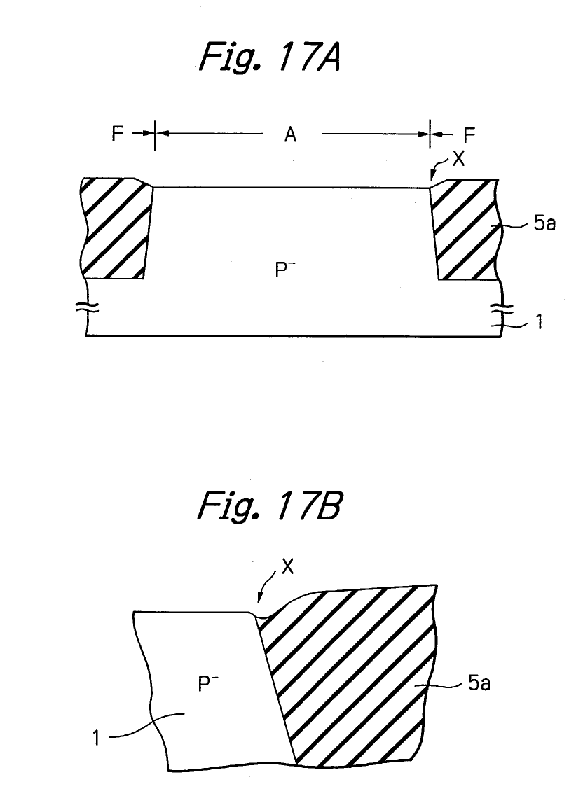

Next, referring to FIGS. 17A and 17B, the sacrifice silicon oxide layer 6 is removed by a wet etching process using diluted fluoric acid.

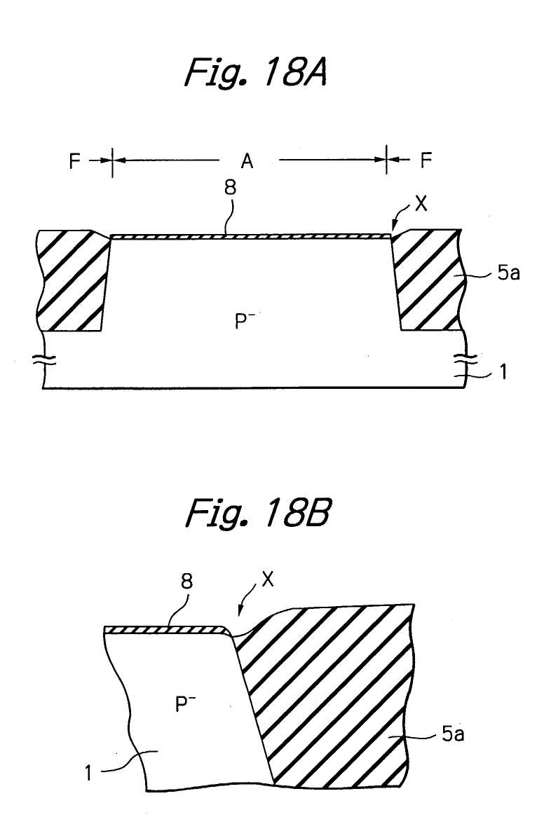

Next, referring to FIGS. 18A and 18B, in the same way as in FIGS. 8A and 8B, an about 2 to 10 nm thick gate silicon oxide layer 8 is thermally grown on the silicon substrate 1.

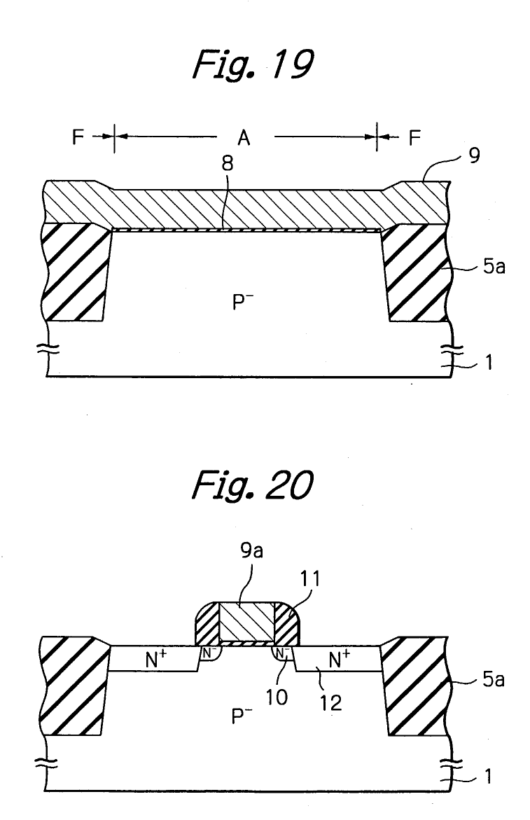

Next, referring to FIG. 19, in the same way as in FIG. 9, an about 100 to 200 nm thick polycrystalline silicon layer 9 is deposited on the entire surface by a CVD process.

Finally, referring to FIG. 20, in the same way as in FIG. 10, the polycrystalline silicon layer 9 is patterned by a photolithography and letching process, so that a gate electrode 9a is formed. Then, a low concentration impurity diffusion region 10 is formed within the silicon substrate 1 in self-alignment with the gate electrode 9a. Also, a sidewall insulating layer 11 is formed on sidewalls of the gate electrode 9a, and then, a high concentration impurity diffusion region 12 is formed within the silicon substrate 1 in self-alignment with the sidewall insulating layer 11. Thus, an LDD type MOS device is completed.

In the manufacturing method as illustrated in FIGS. 11, 12, 13, 14, 15A, 15B, 16A, 16B, 17A, 17B, 18A, 18B, 19 and 20, since the silicon nitride members 7 in the prior art are never formed on the surface of the silicon substrate 1, the surface of the silicon substrate 1 hardly becomes uneven, so that the reliability of the device would not deteriorate.

In the above-described embodiment, although the annealing and oxidizing operation is carried out in an oxygen atmosphere, the annealing and oxidizing operation can be carried out in a water steam atmosphere. Additionally, although the annealing and oxidizing operation is carried out using one kind of rare gas, two or more kinds of rare gas can be used. In this case, Ar gas can be easily obtained at a lower cost. Note that the ratio of rare gas included in the oxygen or water stream is about 10% to 20%.

As explained hereinabove, according to the present invention, since an annealing and oxidizing operation is carried out using rare gas, the surface of a silicon substrate is never nitrized, the reliability of the device would not deteriorate.

1. A method for manufacturing a semiconductor device, comprising the steps of:
forming a pad silicon oxide layer on a silicon substrate;
forming a silicon nitride layer on said pad silicon oxide layer;
patterning said silicon nitride layer and said pad silicon oxide layer to obtain a patterned silicon nitride layer and a patterned pad silicon oxide layer;
etching said silicon substrate using said patterned silicon nitride layer as a mask to form a trench in said silicon substrate;
forming an insulating layer in said trench and on said patterned silicon nitride layer;
performing a chemical mechanical polishing operation upon said insulating layer to expose said patterned silicon nitride layer;
removing said patterned silicon nitride layer and said patterned pad silicon oxide layer to expose said silicon substrate after said chemical mechanical polishing operation is performed; and
performing an annealing and oxidizing operation upon said silicon substrate in an oxygen atmosphere diluted by rare gas, to grow a sacrifice silicon oxide layer on said silicon substrate.

2. The method as set forth in claim 1, wherein said rare gas is at least one of He gas, Ne gas, Ar gas, Kr gas, Xe gas and Rn gas.

3. The method as set forth in claim 1, wherein said annealing and oxidizing operation performing step performs said annealing and oxidizing operation at a temperature of about 950° C. to 1200° C.

4. The method as set forth in claim 1, wherein said annealing and oxidizing operation performing step performs said annealing and oxidizing operation at a temperature of about 1000° C. to 1150° C.

5. A method for manufacturing a semiconductor device, comprising the steps of:
forming a pad silicon oxide layer on a silicon substrate;
forming a silicon nitride layer on said pad silicon oxide layer;
patterning said silicon nitride layer and said pad silicon oxide layer to obtain a patterned silicon nitride layer and a patterned pad silicon oxide layer;
etching said silicon substrate using said patterned silicon nitride layer as a mask to form a trench in said silicon substrate;
forming an insulating layer in said trench and on said patterned silicon nitride layer;
performing a chemical mechanical polishing operation upon said insulating layer to expose said patterned silicon nitride layer;
removing said patterned silicon nitride layer and said patterned silicon oxide layer to expose said silicon substrate after said chemical mechanical polishing operation is performed; and
performing an annealing and oxidizing operation upon said silicon substrate in a water steam atmosphere diluted by rare gas, to grow a sacrifice silicon oxide layer on said silicon substrate.

6. The method as set forth in claim 5, wherein said rare gas is at least one of He gas, Ne gas, Ar gas, Kr gas, Xe gas and Rn gas.

7. The method as set forth in claim 5, wherein said annealing and oxidizing operation performing step performs said annealing and oxidizing operation at a temperature of about 950° C. to 1200° C.

8. The method as set forth in claim 5, wherein said annealing and oxidizing operation performing step performs said annealing and oxidizing operation at a temperature of about 1000 C. to 1150° C.
